(19) United States
(12) Patent Application Publication
(10) Pub. No.: US 2025/0357428 A1
(43) Pub. Date: Nov. 20, 2025

(54) SEMICONDUCTOR STACKED WAFER

(71) Applicant: Winbond Electronics Corp., Taichung City (TW)

(72) Inventors: Ki-Myung Kyung, Zhubei City (TW); San-Ha Park, Hsinchu (TW)

(73) Assignee: Winbond Electronics Corp., Taichung City (TW)

(21) Appl. No.: 19/095,044

(22) Filed: Mar. 31, 2025

Related U.S. Application Data
(60) Provisional application No. 63/648,132, filed on May 15, 2024.

(51) Int. Cl. H01L 25/065; G11C 29/44; H01L 25/18

(52) U.S. Cl. CPC H01L 25/0657; G11C 29/44; H01L 25/18; G11C 2029/4402; H01L 2225/06596

(57) ABSTRACT

A semiconductor stacked wafer includes a plurality of wafers, a reserve wafer and a repair information block. Each of the wafers may include a plurality of dies, and the wafers including a logic wafer having a plurality of logic dies. The reserve wafer is configured to repair a target wafer among the wafers in accordance with a repair enable signal and repair information signals. The repair information block is located in the reserve wafer or the logic wafer, and the repair information block inputs input signals, and output the repair enable signal and the repair information signals in accordance with the input signals.

### CROSS-REFERENCE TO RELATED APPLICATION

This application claims the priority benefit of U.S. provisional application Ser. No. 63/648,132, filed on May 15, 2024. The entirety of the above-mentioned patent application is hereby incorporated by reference herein and made a part of specification.

### BACKGROUND

### Technical Field

The disclosure generally relates to a semiconductor device, and more particularly relates to a semiconductor stacked wafer with a repair scheme that may improve yield of the semiconductor stacked wafer.

### Description of Related Art

A stacked wafer including a plurality of semiconductor wafers have been developed and used for fabricating memory devices having a high band width and a large storage capacity. The stacked wafer may be formed by stacking several semiconductor wafers together. However, the yield of stacked wafer drops sharply as the number of the wafers increased.

It is desirable for a novel technique to improve the yield the stacked wafer.

### SUMMARY

In some embodiments, a semiconductor stacked wafer includes a plurality of wafers, a reserve wafer and a repair information block. Each of the wafers may include a plurality of dies, and the wafers may include a logic wafer and a target wafer. The reserve wafer is configured to repair the target wafer among the wafers in accordance with a repair enable signal and repair information signals. The repair information block is located in the reserve wafer or the logic wafer, and the repair information block inputs input signals, and output the repair enable signal and the repair information signals in accordance with the input signals.

In accordance with some embodiments, a semiconductor stacked wafer includes a plurality of wafers, a reserve wafer and a repair information block. Each of the wafers includes a plurality of dies, and the wafers including a logic wafer and a target wafer. Each die of the wafers includes a plurality of input/output (IO) segments. The reserve wafer is configured to repair the target wafer among the wafers in accordance with repair information signals. The reserve wafer includes a plurality of reserve dies, and each of the reserve dies includes a plurality of reserve IO segments corresponding to the IO segments of each die of the wafers. The repair information block is located in the reserve wafer or the logic wafer, and the repair information block inputs input signals and generates repair information signals. The target wafer is repaired in a unit of IO segment, and a target IO segment in the target wafer is replaced by a reserve IO segment in reserve wafer in the repair operation.

In accordance with embodiments of the disclosure, a reserve wafer is added to the semiconductor stack wafer, thereby improving the yield of stacking the wafers. Since a target wafer among the wafers of the semiconductor stack wafer can be repaired in the unit of die, in the unit of pseudo channel, in the unit of memory bank or in the unit of the memory row, the repair scheme of the disclosure can be effectively and flexibly applied in a wide range of products. In addition, IO segments (or IO units) of the target wafer of semiconductor stack wafer can be repaired using the proposed repair scheme. Accordingly, the flexibility of the repair scheme is further improved.

To make the above features and advantages provided in one or more of the embodiments of the disclosure more comprehensible, several embodiments accompanied with drawings are described in detail as follows.

### BRIEF DESCRIPTION OF THE DRAWINGS

FIG. 1 is a schematic diagram of a semiconductor stacked wafer in accordance with some embodiments.

FIG. 2 is a schematic diagram of a memory device that is formed by stacking a plurality of memory dies of a semiconductor stacked wafer in accordance with some embodiments.

FIG. 3A is a schematic diagram of a repair information block for repairing a target die of a target wafer in accordance with some embodiments.

FIG. 3B and FIG. 3C are waveform diagrams of signals in a semiconductor stacked wafer for repairing the target die in accordance with some embodiments.

FIG. 4A is a schematic diagram of a repair information block for repairing a target pseudo channel, a target memory bank or a target row of a target wafer in accordance with some embodiments.

FIG. 4B and FIG. 4C illustrate waveform diagrams of signals in the semiconductor stacked wafer for repairing the target pseudo channel, the target bank or the target row in accordance with some embodiments.

FIG. 5A is a schematic diagram of a repair information block for repairing a target column in a target wafer in accordance with some embodiments.

FIG. 5B and FIG. 5C are waveform diagrams of signals in a semiconductor stacked wafer for repairing the target column in accordance with some embodiments.

FIG. 5D is a schematic diagram of IO segments in memory banks of semiconductor stacked wafer in accordance with some embodiments.

### DESCRIPTION OF THE EMBODIMENTS

References are made in detail to the present preferred embodiments of the invention, examples of which are illustrated in the accompanying drawings. Wherever possible, the same reference numbers are used in the drawings and the description to refer to the same or like parts.

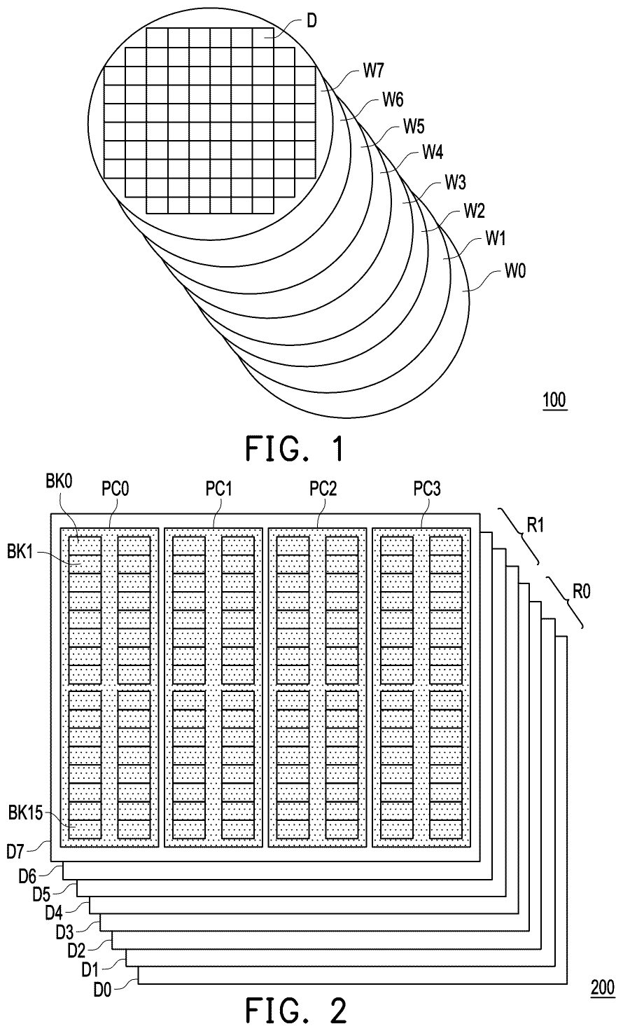

FIG. 1 illustrates a schematic diagram of a semiconductor stacked wafer 100 in accordance with some embodiments. The semiconductor stacked wafer 100 may include a plurality of wafers W0, W1, W2, W3, W4, W5, W6, W7 which are stacked to each other. The wafers W0 to W7 of the semiconductor stacked wafer 100 may be stacked to each other using a wafer-on-wafer stacking technique. Each of the wafers W0 to W7 may include a plurality of semiconductor dies D (also referred to as dies D) that may be stacked to each other to form a memory device such as a high bandwidth memory (HBM). It is appreciated that the number of the wafers W0 to W7 in the semiconductor stacked wafer 100 and the number of dies D per wafer is not limited to any specific numbers. The memory device that is formed by stacking the dies of the semiconductor stacked wafer 100 may be a volatile or non-volatile memories. For example, the memory device may be a dynamic random-access memory (DRAM), but the disclosure is not limited thereto.

The wafers W0 to W7 of the semiconductor stack wafer 100 may include a logic wafer, a reserve wafer, and a plurality of memory wafers. For simplicity, the wafer W0 of the semiconductor stacked wafer 100 is referred to as the logic wafer or a system on chip (SoC) wafer, the wafer W1 is referred to as the reserve wafer, and the wafer W2 to W7 are referred to as memory wafers. In some embodiments, the memory wafer W7 is also referred to as a target wafer or a failed wafer for a repair operation. Please note that the disclosure does not intend to limit the number of the logic wafer, the number of the reserve wafer and the number of the memory wafers in the semiconductor stacked wafer 100. Also, a position and arrangement of the logic wafer, the reserve wafer and the memory wafers in the semiconductor stacked wafer 100 may vary depending on the design requirements.

FIG. 2 illustrates a schematic diagram of a memory device 200 that is formed by stacking a plurality of dies D0, D1, D2, D3, D4, D5, D6, D7 in accordance with some embodiments. The memory device 200 may be a DRAM, but the disclosure is not limited thereto. The dies D0 to D7 are dies of the wafers W0 to W7, respectively. The die D0 in the logic wafer W0 may be referred to as a logic die D0, the reserve die D1 in the reserve wafer W1 may be referred to as reserve die D1, and the dies D2 to D7 in the memory wafers W2 to W7 may be referred to as memory dies D2 to D7. The memory device 200 may include memory ranks R0 and R1, each corresponds to a plurality of wafers. For example, the first memory rank R0 may correspond to wafers W0 to W3, and the second memory rank R1 may correspond to wafers W4 to W7. The memory ranks R0 and R1 can be selected by logic states of rank selection signals SID[0] and SID[1]. For example, when the rank selection signal SID[0] is at the high logic state, the first rank R0 is selected; and when the rank selection signal SID[1] is at the high logic state, the second rank R1 is selected.

Each of the dies D0 to D7 may include a plurality of pseudo channels PC0, PC1, PC2 and PC3, and each of the pseudo channels PC0 to PC3 may include a plurality of memory banks BK0 to BK15. Each of the memory banks BK0 to BK15 may include a plurality of memory rows (not shown) and a plurality of memory columns (not shown). Each of the dies D0 to D7 may further include a plurality of plurality of input/output (IO) segments.

To improve the yield of the stacking dies, a reserve wafer (i.e., the reserve wafer W1) is added to the semiconductor stacked wafer 100 to repair a target wafer (i.e., a target wafer W7) when it determines that there is a failed wafer (i.e., target die W7) in the semiconductor stacked wafer 100. In this way, the yield of the semiconductor stacked wafer 100 is improved.

In some embodiments, the target wafer W7 may be repaired in unit of die. In other words, target dies in the target wafer W7 may be replaced by reserve dies in the reserve wafer W1. In some alternative embodiments, the target wafer W7 may be repaired in unit of pseudo channel, unit of memory bank, unit of memory row. Furthermore, the target IO segments of the target dies of the target wafer W7 may also be repaired using the reserve wafer W1.

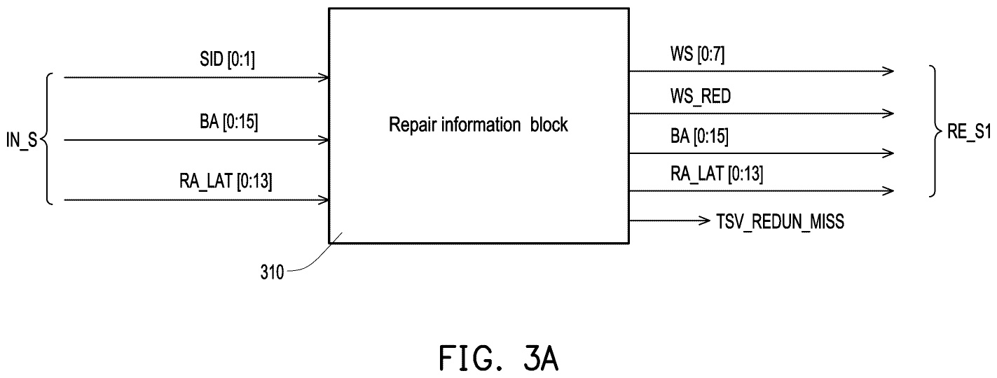

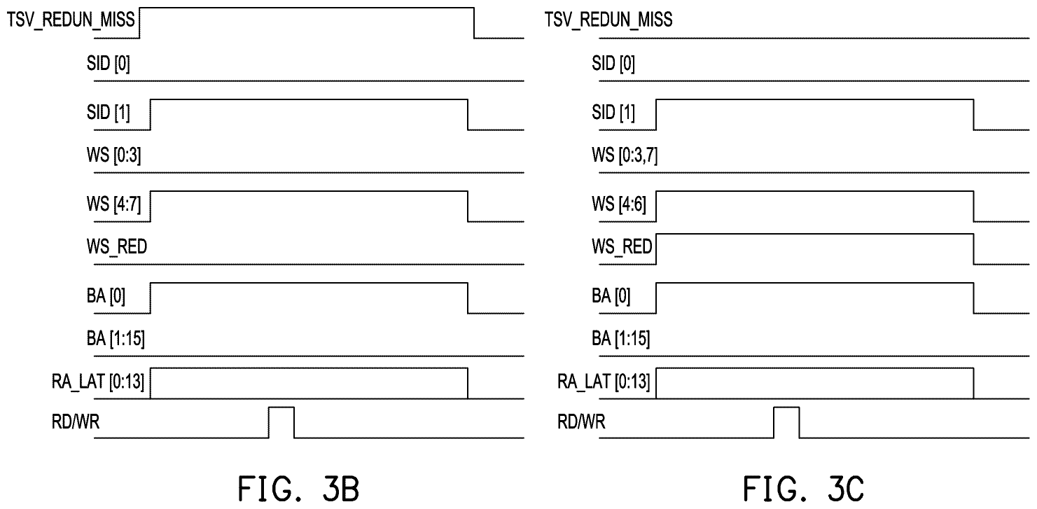

FIG. 3A is a schematic diagram of a repair information block 310 for repairing a target wafer W7 in unit of die in accordance with some embodiments. In other words, the target die in the target wafer W7 may be replaced by a corresponding reserve die in the reserve wafer W1 by using the repair information block 310. The repair information block 310 may be located in the logic wafer W0 or in the reserve wafer W1 of the semiconductor stacked wafer 100. The repair information block 310 may be implemented by hardware circuits, software, or firmware.

The repair information block 310 may receive input signals IN_S and generate a repair enable signal TSV_REDUN_MISS and repair information signals RE_S1. The input signals IN_S may include rank selection signals SID[0:1], bank selection signals BA[0:15], and row selection signals RA_LAT[0:13]. The rank selection signals SID[0:1] are configured to select a memory rank for the repair operation, the bank selection signals BA[0:15] are configured to a target memory bank for the repair operation, and the row selection signals RA_LAT[0:13] are configured to select a memory row for the repair operation.

The repair enable signal TSV_REDUN_MISS may indicate whether the repair operation is performed on the semiconductor stacked wafer 100. For example, when the repair enable signal TSV_REDUN_MISS is at the high logic state, the repair operation is not performed on the semiconductor stacked wafer 100. When the repair enable signal TSV_REDUN_MISS is at the low logic state, the repair operation is performed to repair a target wafer (i.e., the target wafer W7) of the semiconductor stacked wafer 100.

The repair information signals RE_S1 may include wafer selection signals WS[0:7], a reserve wafer selection signal WS_RED, the bank selection signals BA[0:15] and the row selection signals RA_LAT[0:13]. The wafer selection signals WS[0:7] are configured to select the target wafer for the repair operation, and the reserve wafer selection signal WS_RED is configured to select the reserve wafer for the repair operation. The bank selection signals BA[0:15] and the row selection signals RA_LAT[0:13] may be remained to be same as the bank selection signals BA[0:15] and the row selection signals RA_LAT[0:13]input to the repair information block 310.

The repair information block 310 transmits the wafer selection signal WS[0:7] to each die of the wafers W0 to W7. The reserve wafer selection signal WS_RED is transmitted to each die of the reserve wafer W1, and the bank selection signals BA[0:15] and the row selection signal RA_LAT[0:130] are transmitted to all dies of the wafers W0 to W7.

FIG. 3B and FIG. 3C illustrate waveform diagrams of signals in the semiconductor stacked wafer 100 in accordance with some embodiments. The signals illustrated in FIG. 3B and FIG. 3C include the repair enable signal TSV_REDUN_MISS, the rank selection signals SID[0] and SID[1], the wafer selection signals WS[0:3] and WS[4:7], the reserve wafer selection signal WS_RED, the bank selection signals BA[0] and BA[1:15], the row selection signals RA_LAT[0:13] and the read/write signal RD/WR.

The rank selection signals SID[0] and SID[1] may indicate the selected memory rank among the memory ranks R0 and R1. The wafer selection signals WS[0:3] are transmitted to the dies of the wafers W0 to W3, and the wafer selection signals WS[4:7] are transmitted to the dies of the wafer W4 to W7. Logic states of the wafer selection signal WS[0:7] may indicate which wafer among the wafers W0 to W7 is selected for the repair operation. The reserve wafer selection signal WS_RED is transmitted to the reserve dies of reserve wafer W1 to indicate whether the reserve wafer W1 is selected for the repair operation. The bank selection signals BA[0:15] are transmitted to the memory banks BK0 to BK15 to indicate which memory bank is selected, and the row selection signals RA_LAT[0:13] indicate which memory row is selected. The read/write signal RD/WR may indicate a memory operation (i.e., a read operation or a write operation) to be performed.

Referring to FIG. 3B, it assumes that a memory bank BK0 of the second rank R1 is selected and the repair operation is not performed. Since the repair operation is not performed, the repair enable signal TSV_REDUN_MISS is at the high logic state and the reserve wafer selection signal WS_RED is at the low logic state. In addition, since the memory rank R1 is selected, the first rank selection signals SID[0] is at the low logic state and the second rank selection signals SID[1] is at the high logic state. FIG. 3B further shows that the wafer selection signals WS[0:3] are at the low logic state, and the wafer selection signals WS[4:7] are at the high logic state. It indicates that the wafers W0 to W3 are not selected, and the wafers W4 to W7 are selected. The bank selection signal BA[0] is at the high logic state while the bank selection signal BA[1:15] is at the low logic state, indicating that the memory bank BK0 is selected. The row selection signals RA_LAT[0:13] that is transmitted to the memory rows of the selected memory bank BK0 may be at the low logic state or the high logic state depending on selected memory rows for a memory operation (i.e., a read operation or a write operation). The read/write signal RD/WR may be at the low logic state or the high logic state, depending on whether the read operation or the write operation is performed on the selected memory rows.

Referring to FIG. 3C, it assumes that the memory bank BK0 of second memory rank R1 is selected and the repair operation is performed to repair the target wafer W7. Since the repair operation is performed, the repair enable signal TSV_REDUN_MISS is at the low logic state and the reserve wafer selection signal WS_RED is at the high logic state. Since the second memory rank R1 is selected and the target wafer W7 of the second memory rank R1 is selected for the repair operation, the first rank selection signals SID[0] is at the low logic state, the second rank selection signals SID[1] is at the high logic state, the wafer selection signals WS[0:3, 7] that are transmitted to the dies of the wafers W0 to W3 and the target wafer W7 are at the low logic state, and the wafer selection signal WS[4:6] that are transmitted to the dies of the wafers W4 to W6 are at the high logic state. The logic states of the bank selection signals BA[0:15], the row selection signals RA_LAT[0:13] and the read/write signal RD/WR in FIG. 3C are same as those shown in FIG. 3B, thus the detailed description of these signals are omitted hereafter.

A target die of the target wafer W7 receives the wafer selection signal W7 at the low logic state while non-target dies of the target wafer W7 receive the wafer selection signal W7 at the high logic state. Meanwhile, the reserve wafer selection signal WS_RED may select the corresponding reserve die in reserve wafer W1. Accordingly, the target die in the target wafer W7 can be replaced by the corresponding reserve die in the reserve wafer W1. In this way, the target wafer W7 can be repaired in the unit of die using the reserve wafer and the repair information signals RE_S1 output by the repair information block 310.

In some embodiments, information regarding the target die of the target wafer W7 may be stored in the repair information block 310. In a normal operation, when the target die of the target wafer W7 is accessed, it may replace the access to the failed die by an access to the corresponding reserve die in the reserve wafer W1.

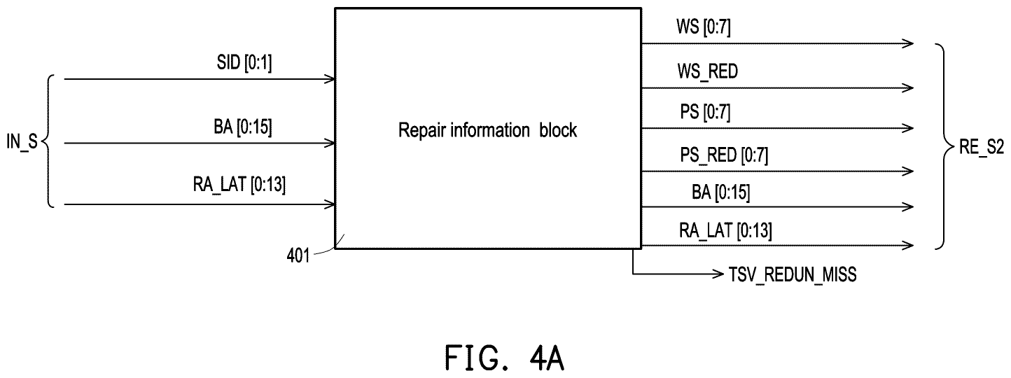

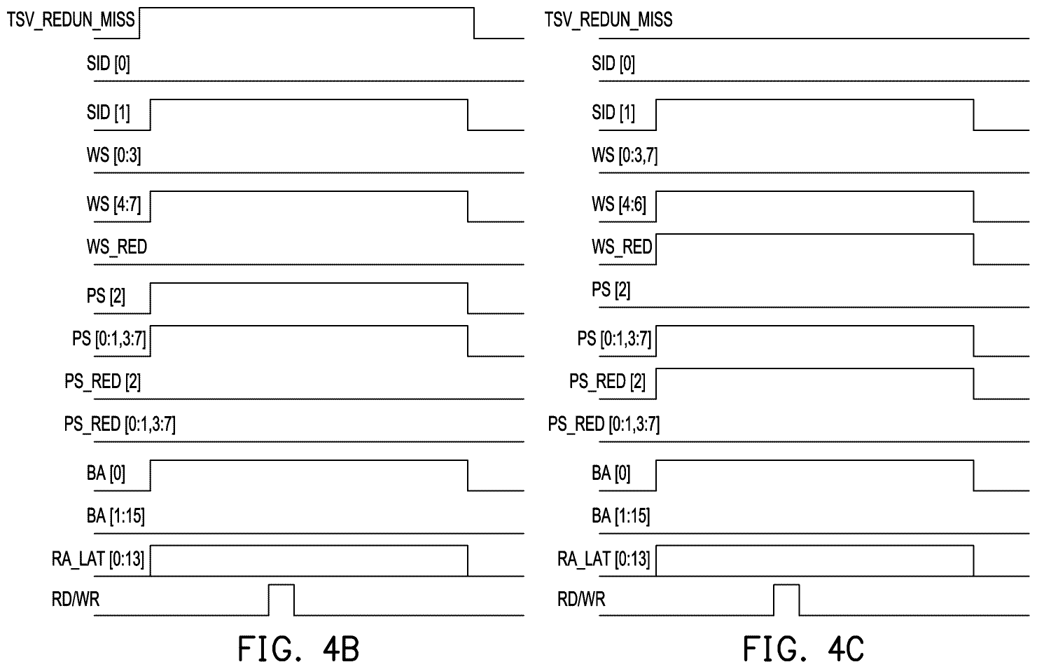

FIG. 4A is a schematic diagram of a repair information block 410 for repairing a target pseudo channel, a target memory bank or a target row of a target wafer in accordance with some embodiments. It assumes that the target pseudo channel is a pseudo channel PC2, the target memory target bank is the memory bank BK0, and the target wafer is the wafer W7.

The repair information block 410 may receive input signals IN_S and generate a repair enable signal TSV_REDUN_MISS and repair information signals RE_S2. The input signals IN_S and the repair enable signal TSV_REDUN_MISS of the repair information block 410 in FIG. 4A may be same as the input signals IN_S and the repair enable signal TSV_REDUN_MISS of the repair information block 310 in FIG. 3A, thus the detailed description of the input signals IN_S and the repair enable signal TSV_REDUN_MISS in FIG. 4A is omitted hereafter.

When the target wafer W7 is repaired in the unit of the pseudo channel, the repair information signals RE_S2 may include wafer selection signals WS[0:7], a reserve wafer selection signal WS_RED, pseudo channel selection signals PS[0:7] and reserve pseudo channel selection signals PS_RED[0:7]. When the target wafer W7 is repaired in the unit of the pseudo channel, the target pseudo channel PC2 in the target wafer W7 may be replaced by a corresponding reserve pseudo channel in the reserve wafer W1.

When the target wafer W7 is repaired in the unit of memory bank, the repair information signals RE_S2 may further include the bank selection signals BA[0:15] in addition to the wafer selection signals WS[0:7], the reserve wafer selection signal WS_RED, the pseudo channel selection signals PS[0:7], and the reserve pseudo channel selection signals PS_RED[0:7]. When the target wafer W7 is repaired in the unit of the memory bank, the target memory bank BK0 in the target wafer W7 may be replaced by a corresponding reserve memory bank in the reserve wafer W1.

When the target wafer W7 is repaired in the unit of memory row, the repair information signals RE_S2 may further include row selection signals RA_LAT[0:13] in addition to the wafer selection signals WS[0:7], the reserve wafer selection signal WS_RED, the pseudo channel selection signals PS[0:7], the reserve pseudo channel selection signals PS_RED[0:7], and the bank selection signals BA[0:15]. When the target wafer W7 is repaired in the unit of the memory row, the target memory row in the target wafer W7 may be replaced by a corresponding reserve memory row in the reserve wafer W1.

The wafer selection signals WS[0:7] are configured to select the target wafer (i.e., the wafer W7) for the repair operation, and the reserve wafer selection signal WS_RED is configured to select the reserve wafer (i.e., wafer W1) for the repair operation. The pseudo channel selection signals PS[0:7] are configured to select the target pseudo channel (i.e., pseudo channel PC2) for repair operation, and the reserve pseudo channel selection signals PS_RED[0:7] are configured to select the corresponding reserve pseudo channel in the reserve wafer W1 for repair operation. The bank selection signals BA[0:15] are configured to select a target memory bank (i.e., memory bank BK0) for the repair information. The row selection signals RA_LAT[0:13] is configured to select a target memory row for the repair operation. The bank selection signals BA[0:15] and the row selection signals RA_LAT[0:13] may be remained to be same as the bank selection signals BA[0:15] and the row selection signals RA_LAT[0:13] input to the repair information block 410.

The repair information block 410 transmits the wafer selection signals WS[0:7] and the pseudo channel selection signals PS[0:7] to each die of the wafers W0 to W7. The reserve wafer selection signal WS_RED and the reserve pseudo channel selection signals PS_RED[0:7] are transmitted to each die of the reserve wafer W1. The bank selection signals BA[0:15] and the row selection signals RA_LAT[0:130] are transmitted to all dies of the wafers W0 to W7.

FIG. 4B and FIG. 4C illustrate waveform diagrams of signals in the semiconductor stacked wafer 100 for repairing the target pseudo channel, the target bank or the target row in accordance with some embodiments. The signals illustrated in FIG. 4B and FIG. 4C include all the signals shown in FIG. 3B and FIG. 3C. Furthermore, FIG. 4B and FIG. 4C further show waveform diagram of the pseudo channel selection signals PS[0:7] and the reserve pseudo channel selection channel PS_RED[0:7].

Referring to FIG. 4B, the waveforms of the repair enable signal TSV_REDUN_MISS, the rank selection signals SID[0] and SID[1], the wafer selection signals WS[0:3] and WS[4:7], the reserve wafer selection signal WS_RED, the bank selection signals BA[0:15], the row selection signals RA_LAT[0:13] and the read/write signal RD/WR in FIG. 4B are same as those in the FIG. 3B, thus the detailed description is omitted hereafter. FIG. 4B further shows the waveforms of the pseudo channel selection signals PS[2] and PS[0:1,3:7], and the reserve pseudo channel selection signals PS_RED[2] and PS_RED[0:1,3:7]. In FIG. 4B, the pseudo channel selection signals PS[2] and PS[0:1,3:7] are at the high logic state, and the reserve pseudo channel selection signals PS_RED[2] and PS_RED[0:1,3:7] are at the low logic state. As such, no pseudo channel of the target wafer W7 and no reserve pseudo channel of the reserve wafer W1 are selected, and the repair operation is not performed.

Referring to FIG. 4C, the waveforms of the repair enable signal TSV_REDUN_MISS, the rank selection signal SID[0] and SID[1], the wafer selection signals WS[0:3] and WS[4:7], the reserve wafer selection signal WS_RED, the bank selection signals BA[0:15], the row selection signals RA_LAT[0:13] and the read/write signal RD/WR in FIG. 4C are same as those in the FIG. 3C, thus the detailed description is omitted hereafter.

FIG. 4C further shows the waveforms of the pseudo channel selection signals PS[2] and PS[0:1,3:7], and the reserve pseudo channel selection signals PS_RED[2] and PS_RED[0:1,3:7]. In FIG. 4C, the pseudo channel selection signal PS[2] that is transmitted to the target pseudo channel PC2 of the target wafer W7 is at the low logic state, and the pseudo channel selection signals [0:1,3:7] that are transmitted to the non-target pseudo channels PC0 to PC1 and PC3 to PC7 of the target wafer W7 are at the high logic state. The reserve pseudo channel selection channel PS_RED[2] that is transmitted to the reserve pseudo channel corresponding to the target pseudo channel PC2 is at the high logic state, and the reserve pseudo channel selection channels PS_RED[0:1, 3:7] that are transmitted to the reserve pseudo channels corresponding to non-target pseudo channels PC0 to PC1 and PC3 to PC7 of the target wafer W7 are at the low logic state. In this way, the target pseudo channel PC2 may be replaced by the corresponding reserve pseudo channel in the reserve wafer W1 in the repair operation. Accordingly, the target wafer W7 is repaired in the unit of pseudo channel.

When the target wafer W7 is repaired in unit of memory bank, the repair information signals RE_S2 further include the bank selection signals BA[0] and BA[1:15]. As shown in FIG. 4C, the bank selection signal BA[0] may be in the high logic state and the bank selection signals BA[1:15] may be in the low logic sate. In this way, the target memory bank BK0 of the target pseudo channel PC2 of the target wafer W7 may be replaced by a corresponding reserve memory bank in the reserve wafer W1 in the repair operation.

When the target wafer W7 is repaired in unit of memory row, the repair information signals RE_S2 further include the row selection signals RA_LAT[0:13]. As shown in FIG. 4C, the row selection signals RA_LAT[0:13] may be selectively in the low logic state or in the high logic state depending on the which row of the target memory bank is repaired. The row selection signal that is transmitted to the target row is in the high logic state, and the row selection signals that are transmitted to the non-target rows are in the low logic state. Accordingly, the target memory row of the target memory bank of the target pseudo channel of the target wafer can be repaired. In this way, the failed wafer W7 can be repair in the unit of memory row.

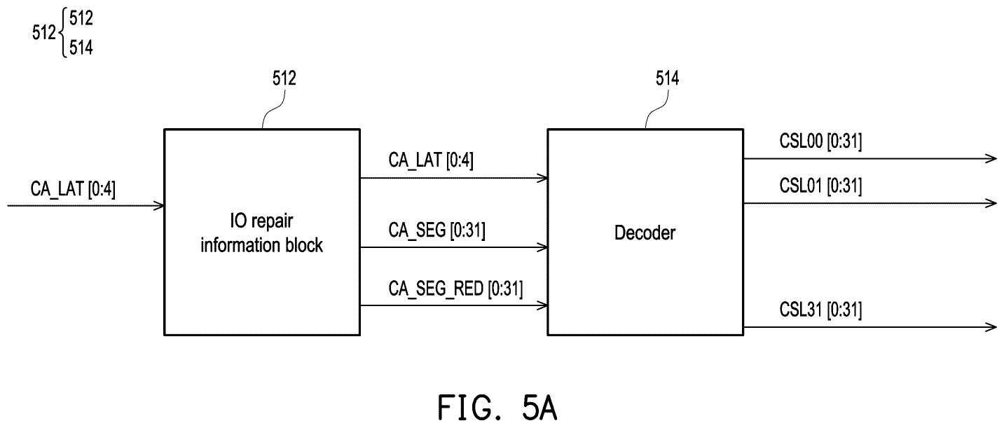

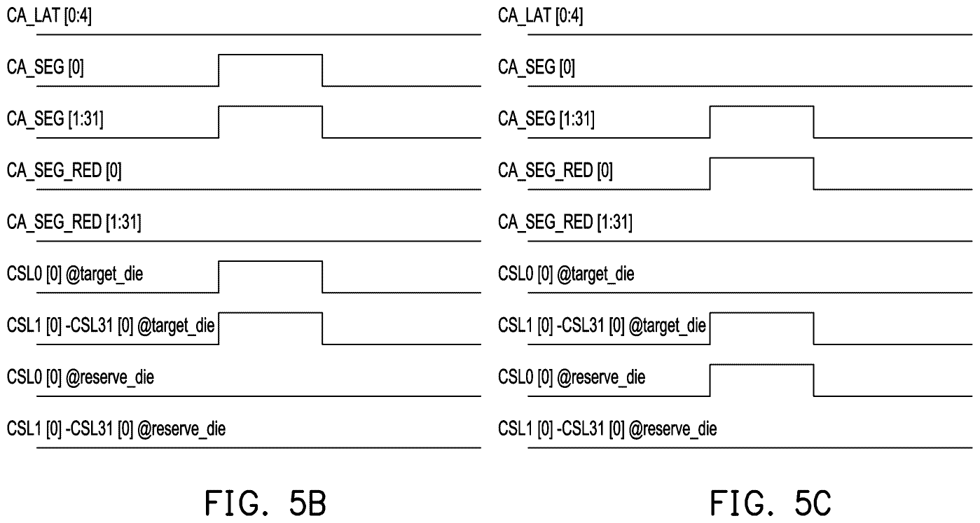

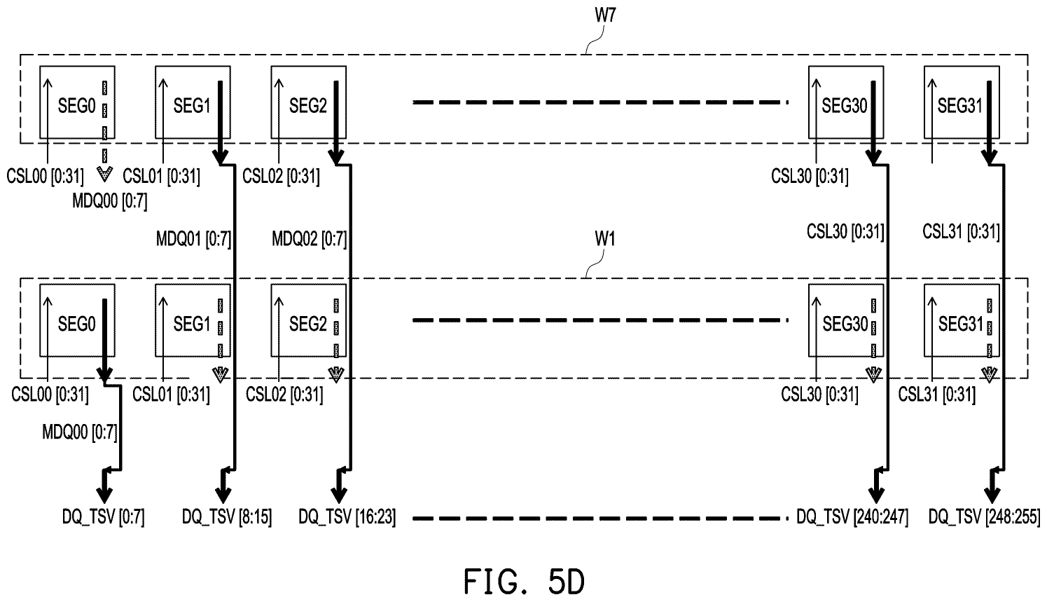

FIG. 5A illustrates a schematic diagram of a repair information block 510 for repairing the target wafer W7 in unit of IO segment in accordance with some embodiments. The repair information block 510 may include an IO repair information block 512 and decoders 514. The IO repair information block 512 is located at the logic die W0 or in the reserve die W1, and the decoders 514 are in all dies of the wafers W0 to W7.

In FIG. 5A, input signals of the IO repair information block 512 include a column address signals CA_LAT[0:4], and output signals of the IO repair information block 512 include the column address signals CA_LAT[0:4], IO segment selection signals CA_SEG[0:31], and reserve IO segment selection signals CA_SEG_RED[0:31]. The output signals of the IO repair information block 512 are provided to the decoders 514. The decoders 514 in the reserve dies of the reserve wafer W1 may be controlled by the reserve IO segment selection signals CA_SEG_RED[0:31], and the decoders 514 in the dies of the wafers W0 and W1 to W7 may be controlled by the IO segment selection signals CA_SEG [0:31]. Each decoder 514 is configured to decode the column address signal CA_LAT[0:4] to generate column selection signals CSL[0:31] for the repair operation.

In some embodiments, the column address signals CA_LAT[0:4] output by the IO repair information block 512 are same as the column address signal CA_LAT[0:4] input to the IO repair information block 512. The IO segment selection signals CA_SEG[0:31] may be used by the target dies of the target wafer W7 to control IO segments of the target wafer W7. The reserve IO segment selection signals CA_SEG_RED[0:31] may be used by the reserve dies of the reserve wafer W1 to control reverse IO segments of the reserve wafer W1. The IO segment selection signals CA_SEG[0:31] may be an inverted signal of the reserve IO segment selection signals CA_SEG_RED[0:31].

FIG. 5B and FIG. 5C show waveform diagrams of signals for repairing the IO segment SEG0 of the target wafer W7 in accordance with some embodiments. The signals shown in FIG. 5B and FIG. 5C include column address signals CA_LAT[0:4], the IO segment selection signals CA_SEG[0] and CA_SEG[1:31], the reserve IO segment selection signals CA_SEG_RED[0] and CA_SEG_RED[1:31], the column selection signals CSL0[0]@target_die and CSL1[0]-CSL31[0]@target_die, and column selection signals CSL0[0]@reserve_die and CSL1[0]-CSL31[0]@reserve_die. The IO segment selection signals CA_SEG[0] and CA_SEG[1:31] may select the IO segment in the target wafer W7 for the repair operation. The reserve IO segment selection signals CA_SEG_RED[0] and CA_SEG_RED[1:31] may select select the reserve IO segment in the reserve wafer W1 for the repair operation. The column selection signals CSL0[0]@target_die and CSL1[0]-CSL31[0]@target die may select columns at the target die (i.e., target die W7) for the repair operation. The column selection signals CSL0[0]@reserve_die and CSL1[0]-CSL31[0]@target_die may select columns at the reserve die for the repair operation.

FIG. 5B illustrates the waveform of the signals when the column repair operation is not enabled. As shown in FIG. 5B, all IO segment selection signals CA_SEG[0] and CA_SEG[1:31] are at the high logic state. Meanwhile, all the IO reserve segment selection signals CA_SEG_RED[0] and CA_SEG_RED[1:31] are at the low logic state. Furthermore, the column selection signals CSL0[0]@target_die and CSL1[0]-CSL31[0]@target_die are at the high logic state, and the column selection signals CSL0[0]@reserve_die and CSL1[0]-CSL31[0]@reserve_die are at the low logic state. Accordingly, the repair operation will not be performed to repair the target IO segment in the target wafer W7.

FIG. 5C illustrates the waveform of the signals when the repair operation is enabled to repair the IO segment SEG0 of the wafer W7 in accordance with some embodiments. As shown in FIG. 5C, the IO segment selection signals CA_SEG[0] that are transmitted to the target IO segment SEG0 in the target wafer W7 is at the low logic state, while the IO segment selection signals CA_SEG[1:31] that are transmitted to non-target segments are at the high logic state. Meanwhile, the reserve IO segment selection signals CA_SEG_RED[0] that is transmitted to the reserve IO segment corresponding to the target IO segment SEG0 is at the high logic state, and the IO segment selection signals CA_SEG_RED[1:31] that are transmitted to the reserve IO segments corresponding to non-target IO segments are at the low logic state. Accordingly, the target IO segment SEG0 in the target wafer W7 and the reserve IO segment SEG0 in the reserve wafer W1 are selected for the repair operation.

FIG. 5C further shows that the column selection signal CSL0[0]@target_die that is transmitted to the target IO segment is at the low logic stage, while the column selection signals CSL1[0]-CSL31[0]@target die that are transmitted to the non-target IO segments is at the high logic stage. Meanwhile, the reserve column selection signal CSL0[0]@reserve_die that is at the high logic state, and the reserve column selection signals CSL1[0]-CSL31[0]@reserve_die are at the low logic state. Accordingly, the target IO segment at the target die and the reserve IO segment at the reserve die are selected for the repair operation. The target IO segment at the target die of the target wafer (i.e., wafer W7) can be replaced with the reserve IO segment column at the reserve die of the reserve wafer (i.e., wafer W1). In this way, the target wafer W7 can be repaired in the unit of IO segment.

FIG. 5D illustrates a repair operation to replace the target IO segment SEG0 of the target wafer W7 with the corresponding reserve IO segment SEG0 of the reserve wafer W1 in accordance with some embodiment. As shown in FIG. 5D, each of the wafers W1 and W7 include a plurality of IO segments SEG0 to SEG31. Each of the IO segments SEG0 to SEG31 may receive input column selection signal CLxx[0:31], in which xx represents the IO segment among the IO segments SEG0 to SEG31. For example, xx of 00 represent the IO segment SEG0, and xx of 31 represent IO segment SEG31. Each of the IO segments SEG0 to SEG31 may output data MDQxx[0:7]. The data MDQxx[0:7] outputted by the IO segments SEG0 to SEG31 may be combined to be output data DQ_TSV[0:255] of the IO segments SEG0 to SEG31.

As shown in FIG. 5D, when the target IO segment SEG0 of the target wafer W7 is replaced by the corresponding IO segment SEG0 of the reserve wafer W1, the data output by the IO segment SEG0 of the target wafer W7 will be replaced by the data MDQ00[0:7] output by the IO segment SEG0 of the target wafer W1. In this way, the target wafer W7 can be repaired in the unit of IO segments or IO units.

In the above embodiments, the semiconductor stacked wafer may include a reserve wafer for repairing a target wafer (or a failed wafer) in the semiconductor stacked wafer. The repair operation may be performed using repair information block that are located at a logic wafer or the reserve wafer of the semiconductor stacked wafer. In this way, the yield of the semiconductor stacked wafer is improved. Furthermore, the repair operation can be performed in a unit of die, a unit of pseudo channel, a unit of memory bank, a unit of memory row, the flexibility of the repair scheme is improved. The IO segments of the target wafer can be repair as well, thereby further improving the flexibility of the repair scheme.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor stacked wafer, comprising:
a plurality of wafers, each including a plurality of dies, the wafers including a logic wafer and a target wafer;
a reserve wafer, configured to repair the target wafer among the wafers in accordance with a repair enable signal and repair information signals;
a repair information block, located in the reserve wafer or the logic wafer, inputting input signals, and outputting the repair enable signal and the repair information signals in accordance with the input signals.

2. The semiconductor stacked wafer according to claim 1, wherein
when the repair enable signal is in a first logic state, a repair operation to repair the target wafer is disabled;
when the repair enable signal is in a second logic state, the repair operation to repair the target wafer is enabled.

3. The semiconductor stacked wafer according to claim 2, wherein
the target wafer is repaired in a unit of die, and
a target die in the target wafer is replaced by a reserve die in reserve wafer in the repair operation.

4. The semiconductor stacked wafer according to claim 3, wherein
the input signals include a rank selection signal, a bank selection signal, and a row selection signal, and
the repair information signals include a target wafer selection signal, a reserve wafer selection signal, the bank selection signal and the row selection signal, wherein the target wafer selection signal is configured to select the target wafer for the repair operation, and the reserve wafer selection signal is configured to select the reserve wafer for the repair operation.

5. The semiconductor stacked wafer according to claim 4, wherein
the repair information block transmits the target wafer selection signal to the dies of the wafers,
the repair information block transmits the reserve wafer selection signal to reserve dies of the reserve wafer, and
the repair information block transmits the bank selection signal and the row selection signal to the dies of the wafers and the reserve dies of the reserve wafer.

6. The semiconductor stacked wafer according to claim 4, wherein
in the repair operation to repair the target wafer, the reserve wafer selection signal is in the first logic state, the target wafer selection signal that is transmitted to the target die of the target wafer is in the second logic state, and the target wafer selection signal that is non-target dies of the target wafer is in the first logic state.

7. The semiconductor stacked wafer according to claim 4, wherein
when the repair operation to repair the target wafer is disabled, the reserve wafer selection signal is in second logic state, and the target wafer selection signal that is transmitted to all dies of the target wafer is in the first logic state.

8. The stacked wafer according to claim 2, wherein
each of the dies includes a plurality of pseudo channels,
the target wafer is repaired in a unit of pseudo channel, and
a target pseudo channel of the target wafer is replaced by a reserve pseudo channel in the reserve wafer in the repair operation.

9. The semiconductor stacked wafer according to claim 8, wherein
the input signals include a rank selection signal, a bank selection signal, and a row selection signal, and
the repair information signals include a target wafer selection signal, a reserve wafer selection signal, a pseudo-channel selection signal, a reserve pseudo-channel selection signal, the bank selection signal and the row selection signal,
wherein the pseudo-channel selection signal is configured to select the target pseudo-channel of the target die of the target wafer for the repair operation, the reserve pseudo-channel selection signal is configured to select a reserve pseudo-channel corresponding to the target pseudo-channel.

10. The semiconductor stacked wafer according to claim 9, wherein
the repair information block transmits the target wafer selection signal and the pseudo-channel selection signal to dies of the wafers,
the repair information block transmits the reserve wafer selection signal and the reserve pseudo-channel selection signal to reserve dies of the reserve wafer, and
the repair information block transmits the bank selection signal and the row selection signal to the dies of the wafers and the reserve dies of the reserve wafer.

11. The semiconductor stacked wafer according to claim 9, wherein
in the repair operation to repair the target pseudo channel, the reserve wafer selection signal is in a first logic state, the target wafer selection signal that is transmitted to the target die of the target wafer is in the second logic state, the target wafer selection signal that is transmitted to non-target dies in the target wafer is in the first logic state,
the pseudo-channel selection signal that is transmitted to the target pseudo channel of the target die is in the second logic state, and the pseudo-channel selection signal that is transmitted to non-target pseudo channels of the target die is in the second logic state, and
the reserve pseudo-channel selection signal that is transmitted to the reserve pseudo channel corresponding to the target pseudo channel is in the first logic state, and the reserve pseudo-channel selection signal that is transmitted to the reserve pseudo channels corresponding to non-target pseudo channels is in the second logic state.

12. The semiconductor stacked wafer according to claim 9, wherein
when the repair operation to repair the target wafer is disabled, the reserve wafer selection signal is in the second logic state, the target wafer selection signal is in the first logic state, the pseudo-channel selection signal is in the first logic state, and the reserve pseudo-channel selection signal is in the second logic state.

13. The semiconductor stacked wafer according to claim 2, wherein
each of the dies includes a plurality of pseudo channels,
each of the pseudo channels includes a plurality of memory banks,
the target wafer is repaired in a unit of memory bank, and
a target memory bank of a target pseudo channel of the target wafer is replaced by a reserve memory bank in reserve wafer in the repair operation.

14. The semiconductor stacked wafer according to claim 3, wherein
the input signals include a rank selection signal, a bank selection signal, and a row selection signal, and
the repair information signals include a target wafer selection signal, a reserve wafer selection signal, a pseudo-channel selection signal, a reserve pseudo-channel selection signal, the bank selection signal BA and the row selection signal,
wherein the target wafer selection signal is configured to select the target wafer, the pseudo-channel selection signal is configured to select the target pseudo-channel, and the bank selection information is configured to select the target memory bank.

15. The semiconductor stacked wafer according to claim 2, wherein
each of the dies includes a plurality of pseudo channels,
each of the pseudo channels includes a plurality of memory banks,
each of the memory banks includes a plurality of memory rows,
the target wafer is repaired in a unit of memory row, and
a target memory row of a target memory bank of a target pseudo channel of the target wafer is replaced by a reserve memory row in reserve wafer in the repair operation.

16. A semiconductor stacked wafer, comprising:
a plurality of wafers, each including a plurality of dies, the wafers including a logic wafer and a target die, wherein each die of the wafers includes a plurality of input/output segments;
a reserve wafer, configured to repair the target wafer among the wafers in accordance with repair information signals, wherein the reserve wafer includes a plurality of reserve dies, and each of the reserve dies includes a plurality of reserve IO segments corresponding to the IO segments of each die of the wafers;
a repair information block, located in the reserve wafer or the logic wafer, inputting input signals, and generating repair information signals,
wherein the target wafer is repaired in a unit of IO segment, and a target IO segment in the target wafer is replaced by a reserve IO segment in reserve wafer in the repair operation.

17. The semiconductor stacked wafer of claim 16, wherein
the input signals include a column address signals,
the repair information signals include an IO segment selection signal, a reserve IO segment selection signal, and a column selection signal,
the IO segment selection signal is configured to select a target IO segment in the target wafer, the reserve IO segment selection signal is configured to select a reserve IO segment corresponding to the target IO segment in the reserve wafer.

18. The semiconductor stacked wafer of claim 16, wherein
in the repair operation to repair the target wafer, the IO segment selection signal that is transmitted to the target IO segment of the target wafer is at the second logic state, the IO segment selection signal that is transmitted to the non-target IO segments of the target wafer is in the first logic state,
the reserve IO segment selection signal that is transmitted to the reserve IO segment corresponding to the target IO segment is in the first logic state, the reserve IO segment selection signal that is transmitted to reserve IO segments corresponding to the non-target IO segments is in the second logic state.

19. The semiconductor stacked wafer of claim 18, wherein
in the repair operation to repair the target wafer, the column selection signal transmitted to the target IO segment of the target wafer is in the second logic state, and the column selection signal transmitted to the non-target IO segments of the target wafer is in the first logic state, and
the reserve column selection signal transmitted to the reserve IO segment corresponding to the target IO segment is in the first logic state, and the column selection signal transmitted to reserve IO segments corresponding to the non-target IO segments is in the second logic state.

20. The semiconductor stacked wafer of claim 19, wherein
when the repair operation to repair the target wafer is disabled, the reserve IO segment selection signal is in the first logic state, the reserve IO segment selection signal is in the second logic state, and the column selection signals transmitted to all IO segments of the target wafer is in the first logic state.
